(19) United States
(12) Patent Application Publication
(10) Pub. No.: US 2026/0322075 A1
(43) Pub. Date: Oct. 15, 2026

(54) III-NITRIDE-BASED VERTICAL CAVITY SURFACE EMITTING LASER (VCSEL) WITH A DIELECTRIC P-SIDE LENS AND AN ACTIVATED TUNNEL JUNCTION

(71) Applicant: The Regents of the University of California, Oakland, CA (US)

(72) Inventors: Nathan Palmquist, Goleta, CA (US); Daniel A. Cohen, Santa Barbara, CA (US); Stephen Gee, Torrance, CA (US); Jared Kearns, Mountain View, CA (US); Shuji Nakamura, Santa Barbara, CA (US)

(73) Assignee: The Regents of the University of California, Oakland, CA (US)

(21) Appl. No.: 19/105,449

(22) PCT Filed: Aug. 22, 2023
(86) PCT No.: PCT/US2023/072619

§ 371 Date: Feb. 21, 2025

Related U.S. Application Data
(60) Provisional application No. 63/399,757, filed on Aug. 22, 2022.
(60) Provisional application No. 63/408,947, filed on Sep. 22, 2022.

(51) Int. Cl. H01S 5/183; H01S 5/30; H01S 5/323

(52) U.S. Cl. CPC H01S 5/18361; H01S 5/18322; H01S 5/18341; H01S 5/18388; H01S 5/3095; H01S 5/323

(57) ABSTRACT

A III-nitride-based vertical cavity surface emitting laser (VCSEL) includes an active region between p-type and n-type layers; and a curved mirror on or above the p-type layer such that the p-type layer is between the active region and the curved mirror. The VCSEL includes a tunnel junction between the p-type layer and a curved mirror, wherein the tunnel junction is a planar tunnel junction and a p++-type layer of the tunnel junction is activated through sidewalls of the VCSEL. The curved mirror is formed on or above the tunnel junction, such that the tunnel junction is between the curved mirror and the p-type layer. The VCSEL further comprises a flat distributed Bragg reflector (DBR) mirror, the curved mirror comprises a curved DBR mirror, the III-nitride active region is between the flat DBR mirror and the curved DBR mirror, and the flat DBR mirror and the curved DBR mirror define a cavity of the VCSEL.

### CROSS REFERENCE TO RELATED APPLICATIONS

This application claims the benefit under 35 U.S.C. Section 119 (e) of the following co-pending and commonly-assigned applications:
U.S. Provisional Application Ser. No. 63/399,757, filed on Aug. 22, 2022, by Nathan Palmquist, Daniel A. Cohen, Stephen Gee, Jared Kearns, and Shuji Nakamura, entitled “III-NITRIDE-BASED VERTICAL CAVITY SURFACE EMITTING LASER (VCSEL) WITH A DIELECTRIC P-SIDE LENS,” attorneys' docket number G&C 30794.0826USP1 (UC 2023-847-1); and
U.S. Provisional Application Ser. No. 63/408,947, filed on Sep. 22, 2022, by Stephen Gee, Nathan Palmquist and Shuji Nakamura, entitled “III-NITRIDE-BASED VERTICAL CAVITY SURFACE EMITTING LASER (VCSEL) WITH AN ACTIVATED TUNNEL JUNCTION,” attorneys' docket number G&C 30794.0828USP1 (UC 2023-853-1);
both of which applications are incorporated by reference herein.

This application is related to the following co-pending and commonly-assigned applications:
U.S. Utility patent application Ser. No. 17/613,659, filed Nov. 23, 2021, by Jared Kearns, Daniel Cohen, Joonho Back, Nathan Palmquist, Tal Margalith, Steven P. DenBaars and Shuji Nakamura, entitled “III-NITRIDE-BASED VERTICAL CAVITY SURFACE EMITTING LASER (VCSEL) CONFIGURATIONS,” attorney's docket no. 30794.0728USWO (UC 2019-934-2);
which application claims the benefit under 35 U.S.C. Section 365 (c) of the following co-pending and commonly-assigned application:

PCT International Patent Application Serial No. PCT/US2020/034955, filed May 28, 2020, by Jared Kearns, Daniel Cohen, Joonho Back, Nathan Palmquist, Tal Margalith, Steven P. DenBaars and Shuji Nakamura, entitled “III-NITRIDE-BASED VERTICAL CAVITY SURFACE EMITTING LASER (VCSEL) CONFIGURATIONS,” attorney's docket no. 30794.0728WOU1 (UC 2019-934-2);
which application claims the benefit under 35 U.S.C. Section 119 (e) of the following co-pending and commonly-assigned applications:
U.S. Provisional Patent Application No. 62/854,046 filed May 29, 2019, by Jared Kearns, Daniel Cohen, Joonho Back, and Shuji Nakamura, entitled “III-NITRIDE-BASED VERTICAL CAVITY SURFACE EMITTING LASER (VCSEL) WITH CURVED MIRROR ON P-SIDE OF THE APERTURE” Attorney's Docket No. 30794.728-US-P1 (2019-934); and
U.S. Provisional Patent Application No. 62/866,183, filed Jun. 25, 2019, by Nathan Palmquist, Jared Kearns, and Shuji Nakamura, entitled “III-NITRIDE VERTICAL-CAVITY SURFACE EMITTING LASERS WITH A HIGH INDIUM CONTENT ACTIVE REGION” Attorney's Docket No. 30794.730-US-P1 (2019-935)
all of which applications are incorporated by reference herein.

### BACKGROUND OF THE INVENTION

### 1. Field of the Invention

This invention relates to a III-nitride vertical cavity surface emitting laser (VCSEL) with a dielectric p-side lens and an activated tunnel junction.

### 2. Description of the Related Art

(Note: This application references a number of different publications as indicated throughout the specification by one or more reference numbers in brackets, e.g., [x]. A list of these different publications ordered according to these reference numbers can be found below in the section entitled “References.” Each of these publications is incorporated by reference herein.)

(The terms “III-nitride”, “III-N”, and “GaN” refer to any alloy of Group-III nitride semiconductors that are described by (B_{w}AlₓGa_{y}In_{z}) N, where 0≤w≤1, 0≤x≤1, 0≤y≤1, 0≤z≤1, and w+x+y+z=1. Compositions can range from containing a single Group-III element to all four Group-III elements. These materials can, and often, include dopants and impurities including scandium (Sc) to make the alloy.)

Vertical cavity surface emitting lasers (VCSELs) have a number of advantages over edge emitting lasers (EELDs) and light emitting diodes (LEDs), including a focused output beam with low divergence, a low threshold current and high output power with a narrow spectrum, and the ability to be processed in dense, two-dimensional arrays. [1] Infrared phosphide and arsenide VCSELs are currently used in a variety of applications, including optical communications, sensing, and high-power arrays, and experience a yearly production volume of approximately 100 million units.

Gallium nitride (GaN) VCSELs have recently been receiving increasing research attention due to their ability to emit in the visible and ultraviolet (UV) regions. This opens up a variety of exciting new applications in displays, solid state lighting, sensing, and communications. One particularly exciting application is visible light communications (VLC), wherein a GaN VCSEL could couple with a phosphor to act as both a natural light source and data transmission device simultaneously. With the increasing proliferation of devices that can access networks, bandwidths are becoming overly crowded. Gaining the ability to transmit certain data via visible wavelengths would greatly expand current bandwidth capabilities.

Continuous-wave (CW) lasing at 462 nm of an electrically injected GaN VCSEL was first demonstrated in 2008 at a temperature of 77K. [2] Since then, considerable progress has been made in terms of output power, efficiency, threshold current, lasing wavelength, and room temperature stability. GaN VCSELs have the potential to enter incredibly lucrative markets, but currently lack the device performance and efficiencies of current comparable commercial products.

Long cavity (>10-λ) GaN VCSEL designs have recently shown promise due to their improved thermal performance and reduced processing constraints. Up until 2022, long cavity designs from Sony held the performance records for CW output power (15.4 mW), threshold current (0.25 mA), and wall plug efficiency (WPE) (13.4%). [3-5] They accomplished this impressive performance by utilizing a cavity with a planar mirror and curved mirror. [6] The curved mirror is necessary because it prevents diffraction and scattering loss that would otherwise occur in long cavities. [7] As cavity length increases, so does diffraction loss; the typical gain of GaN QWs is approximately 1%, so diffraction loss can quickly deteriorate device performance for cavities larger than 10 μm. Sony's curved mirror VCSEL cavity was approximately 28 μm for all of their recent publications. However, converting one of the planar mirrors into a curved mirror is known to provide a stable resonator that forms a beam waist on the planar side, without generating diffraction or scattering loss. As will be shown, the beam waist and propagation throughout the cavity is primarily determined by the cavity length (L) and the radius of curvature (ROC) of the mirror. Sony's design prioritized low threshold conditions by placing the active region approximately at the beam waist (100 nm from the planar mirror). This design led to a well-confined lateral mode at the QWs, with a 4σ width of approximately 3 μm and a record low threshold of 0.25 mA. Recent work on this cavity design have also demonstrated that some of the challenges associated with long cavities, namely multi-longitudinal modes and wide divergence angles (8.5° or greater), can be mitigated or avoided entirely with clever cavity design. [8,9] Overall, the curved mirror design is promising in its ability to reach high output powers and reduce processing constraints associated with short cavities.

In addition to long cavity designs, GaN VCSELs utilizing epitaxial DBRs have been gaining traction as well. Conventional epitaxial DBRs utilize either AlGaN/GaN or AlInN/GaN mirror pairs, with the latter showing superior performance metrics due to AllnN's ability to lattice match to GaN under the right growth conditions. [10] However, both mirror pairs suffer from a low refractive index mismatch, requiring 40 or more periods to reach the requisite reflectivity (>99.5% for emission-side); maintaining the sensitive growth conditions to grow these layers can make epitaxial DBRs difficult to realize.

Recently, nanoporous DBR (NP-DBR) structures have been gaining popularity due to their relative ease of fabrication, their lattice match to GaN, and their high achievable refractive index contrast. [11-13] Due to the high index contrast attainable, a realistic porosity of 36% can achieve 99.5% reflectivity with only 17 periods. Since GaN NP-DBRs were first demonstrated in 2015, multiple groups have achieved lasing with different VCSEL cavity designs. Mishkat-Ui-Masabih et. al. demonstrated the first m-plane VCSEL utilizing a NP-DBR in 2019 [14]; Elafandy et. al. showed that electrical injection into a c-plane GaN VCSEL through the NP-DBR structure exhibited minimal performance penalties to the threshold current, slope efficiency, or nearfield pattern [15]; and finally, Elafandy et. al. showed again that the birefringence of NP-GaN could be exploited to polarization lock c-plane GaN VCSEL arrays. [16]

### SUMMARY OF THE INVENTION

The present invention discloses a III-nitride-based vertical cavity surface emitting laser (VCSEL), and a method of fabricating the VCSEL, the VCSEL comprising a III-nitride active region between a p-type III-nitride layer and an n-type III-nitride layer; and a curved mirror on or above the p-type III-nitride layer, such that the p-type III-nitride layer is between the III-nitride active region and the curved mirror.

The VCSEL further comprises at least one tunnel junction formed on the p-type III-nitride layer, wherein the curved mirror is formed on or above the tunnel junction, such that the tunnel junction is positioned between the curved mirror and the p-type III-nitride layer. An n-type III-nitride current spreading layer may be positioned between the tunnel junction and the curved mirror.

The tunnel junction may be a planar tunnel junction, wherein a p++-type III-nitride layer of the planar tunnel junction is activated through a sidewall of the VCSEL. In this structure, the p++-type III-nitride layer extends to the sidewall of the VCSEL, and a bottom area of the curved mirror may be substantially the same as an area of the planar tunnel junction. Chemical treatments, such as a phosphoric acid dip, ultraviolet-ozone treatment, or buffered hydrofluoric acid dip, may be implemented to further improve activation of the p++-type III-nitride layer.

A current aperture defined by reactive ion etching (RIE) or ion implantation may be used to confine current in the III-nitride active region, resulting in increased gain and efficiency. The ion implantation current aperture is fabricated by ion implantation of aluminum (Al) or boron (B), and allows for activation of the p-type III-nitride layer and a p++-type III-nitride layer.

The VCSEL further comprises a second n-type III-nitride region formed on or above the tunnel junction, wherein the curved mirror includes the second n-type III-nitride region and the second n-type III-nitride region has a curvature forming the curved mirror. The second n-type III-nitride region may have an etched surface having the curvature. The second n-type III-nitride region may comprise n-type GaN nitride or unintentionally doped GaN.

The curved mirror may comprise a dielectric material that is transparent, wherein the dielectric material's surface has a curvature, and a distributed Bragg reflector (DBR) is disposed upon the dielectric material's surface. The dielectric material may comprise a transparent oxide (TO) or a polymer. The dielectric may be removed by dry or wet etching after deposition of the DBR, resulting in a curved DBR mirror separated from other layers by an empty or gas-filled void.

The VCSEL may comprise one or more transparent conducting oxide (TCO) layers on the p-type III-nitride layer, rather than a tunnel junction, wherein the curved mirror is formed on or above the TCO layers, such that the TCO layers are between the curved mirror and the p-type III-nitride layer. The TCO layers may be composed of ITO, ZnO, Ga₂O₃, ZnO, or other materials.

The VCSEL may further comprise a flat DBR mirror, the curved mirror comprises a curved DBR mirror, the III-nitride active region is between the flat DBR mirror and the curved DBR mirror, and the flat DBR mirror and the curved DBR mirror define a cavity of the VCSEL. The cavity may have a total cavity length of more than 8 micrometers. The flat DBR mirror may be a nano-porous (NP)-DBR, InAlN/GaN DBR, dielectric DBR, or other reflector with a reflectivity above 99%.

The curved mirror may be close enough to the III-nitride active region that most of the width of the III-nitride active region is in the path of a light beam generated by the device. The mesa can be etched close to the outside edge of the curved mirror, restricting the current to an area around the curved mirror.

A crystal orientation of III-nitride layers in the VCSEL may be c-plane, semipolar or nonpolar.

### BRIEF DESCRIPTION OF THE DRAWINGS

Referring now to the drawings in which like reference numbers represent corresponding parts throughout:

FIG. 1A is a schematic of a conventional VCSEL with a bottom-side NP DBR and top-side monolithic GaN lens, FIG. 1B is a schematic of a VCSEL with a bottom-side NP DBR and top-side dielectric p-side lens according to this invention, and FIG. 1C is a schematic of a VCSEL with a bottom-side NP DBR and top-side curved dielectric DBR forming an air-gap lens according to this invention.

FIG. 2A is a schematic of a cavity consisting of a planar mirror and curved mirror with the active region at the beam waist, or farther up the cavity, and FIG. 2B is a graph of beam profile (μm) vs. device depth (μm) showing the calculated growth of the beam diameter across a 13 μm planar-curved mirror cavity with lenses with different ROC.

FIG. 3 is a graph of Light Intensity Fraction vs. Wavelength (nm) showing the optimized NP DBR structure compared to a 1D transmission matrix model.

FIG. 4A is a graph of Intensity (a.u.) vs. Wavelength (nm) showing the spectrum of a 9 μm aperture VCSEL under a 1000 ns 1% duty cycle pulsed operation, FIG. 4B is a graph of voltage (V) and power (mW) vs. Current Density (kA/cm²) showing the light-current density-voltage (LJV) data under a 1000 ns 1% duty cycle pulsed (solid line) and continuous-wave (CW) operation (dashed line), and FIGS. 4C and 4D are nearfield images of the 9 μm VCSEL below and above threshold showing fundamental lateral mode lasing.

FIG. 5 is a graph of Normalized Photoluminescence (PL) Intensity (a.u.) vs. Wavelength (nm) showing the normalized PL intensities of active regions subjected to various regrowth conditions compared to calculated PL emission intensity using a dielectric lens.

FIG. 6A is a cross-sectional schematic of a VCSEL with a planar tunnel junction implemented just below the curved mirror, according to an embodiment of the present invention.

FIG. 6B is a cross-sectional schematic of a VCSEL with a current aperture formed by ion implantation, according to an embodiment of the present invention.

FIG. 7 is a flowchart illustrating an example process for fabricating the epitaxial device structure, includes the following steps:

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Overview

Improvements to III-nitride-based VCSELs can be accomplished through the use of a dielectric p-side lens, and a planar tunnel junction (TJ) activated through sidewalls of the VCSEL.

The use of a dielectric p-side lens in a III-nitride-based VCSEL is shown herein to be a viable way to improve device performance by reducing loss within the cavity and improving active region emission intensity. Additionally, the dielectric p-side lens is a top-side lens allowing for the active region to be farther up in the cavity, increasing the maximum width of the beam and current aperture. One or more embodiments of the present invention comprise a III-nitride LED or III-nitride VCSEL with a curved dielectric p-side lens as an active or passive optic component.

The use of a GaN TJ provides a method to achieve lower loss than current spreading layers. [28] Due to the poor electrical conductivity of p-GaN layers, current spreading layers are often implemented on the p-side of GaN optoelectronics. Often, a transparent conductive oxide (TCO), in particular, Indium Tin Oxide (ITO), is used. However, ITO has a high absorption coefficient at visible wavelengths. [27] While this effect may be minimal in LEDs, the low per-pass optical gain in VCSEL cavities (roughly 1%) requires loss to be minimized.

On the other hand, GaN has a lower absorption coefficient than ITO at visible wavelengths, leading to lower losses. Another benefit provided by using GaN TJs is that buried TJs can act as a current aperture. [29] These buried TJs have been successfully implemented in VCSEL designs by the inventors at the University of California, Santa Barbara (UCSB). [30,31]

However, GaN TJs grown by metal-organic chemical vapor deposition (MOCVD) have a high turn-on voltage compared to ITO. Due to the high hydrogen environment in MOCVD during n-GaN regrowth, the magnesium acceptors in p-GaN are passivated with hydrogen. These acceptors can be activated through thermal annealing, in which the hydrogen diffuses out of the sidewalls. [32] However, as buried TJs are buried below a larger n-GaN layer, which acts as a diffusion barrier for hydrogen, the activation efficiency of the p-GaN is low and leads to a larger turn-on voltage. [33,34] Methods such as selective area growth have been proposed to activate p-GaN in TJ LEDs, but such a method would introduce damaging scattering loss in VCSELs. [35]

The use of a planar TJ in a III-nitride-based VCSEL is a viable way to improve device performance by reducing loss within the cavity, as well as reducing the turn-on voltage of the TJ through sidewall treatment and activation. A small device mesa or an ion implantation current aperture can be used to confine current, resulting in increased gain and efficiency. The addition of the ion implantation current aperture for the TJ, rather than a buried TJ, allows for better activation of the p-type GaN. This reduces the turn-on voltage of the device, allows for improved WPE, and can be used to create higher power devices.

The use of a dielectric p-side lens and a planar TJ in III-nitride-based VCSELs is described in more detail below.

### Long Cavity Design

Sony's VCSEL cavity design utilized a bottom-side curved mirror and a top-side planar mirror ~100 nm above their active region. To fabricate the bottom-side curved mirror, they first polished the substrate down to a thickness of approximately 30-50 μm, and then formed the lens (for a final cavity thickness of approximately 28 μm). This technique creates significant processing challenges, as the thin 28 μm substrates are fragile and prone to cracking. To combat this, the UCSB lens design is fabricated on the top-side, and the planar DBR is on the bottom side (with the end device also being bottom-side emitting). This simultaneously solves both the alignment and processing issues, and it also introduces a new advantage; the active region is far away from the planar DBR. This dynamic will be explored in the following section.

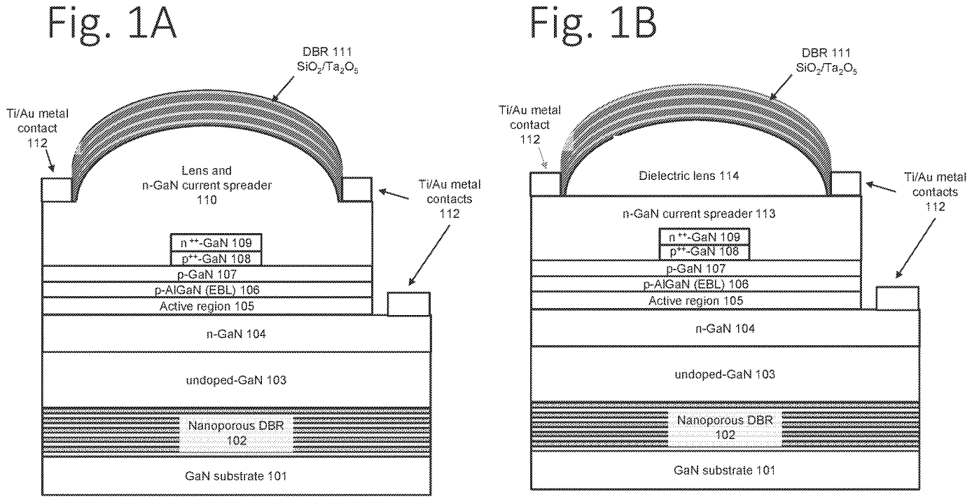

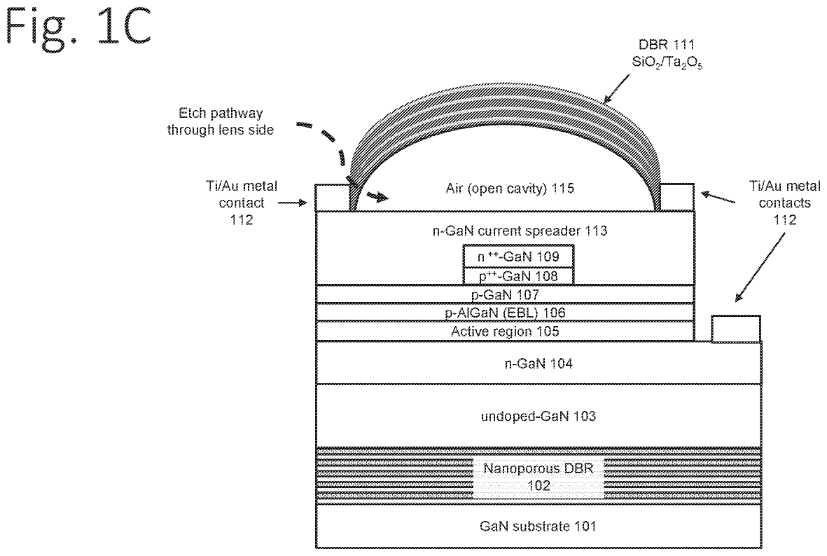

FIGS. 1A, 1B, and 1C are VCSEL variations, which include a GaN substrate 101, nanoporous (NP) DBR 102, undoped-GaN 103, n-GaN 104, active region 105, p-AlGaN electron blocking layer (EBL) 106, p-GaN 107, p++-GaN 108, n++-GaN 109, n-GaN current spreader+lens 110, DBR 111, metal contacts 112, n-GaN current spreader 113, dielectric lens 114 and an open cavity comprised of air 115.

Specifically, FIG. 1A is a schematic of a conventional VCSEL with a bottom-side NP DBR 102 and top-side monolithic GaN lens 100, FIG. 1B is a schematic of a VCSEL with a bottom-side NP DBR 102 and top-side dielectric lens 114, and FIG. 1C is a schematic of a VCSEL with a bottom-side NP DBR 102 and top-side curved dielectric DBR 111 forming an air-gap lens 115.

The NP DBR 102 provides greater consistency and throughput compared to a flip-chip bonded process design and will be used as the bottom side mirror. The substrate 101 is nonpolar to take advantage of the higher material gain [17], and ability to grow thick quantum wells, however, many kinds of substrates could be used for this invention, such as c-plane GaN, semipolar GaN, AlN, Al template grown sapphire and others.

### III-Nitride Monolithic Lens Optimization

Microfabrication of lenses via photolithography and resist reflow have long been used to manufacture lens arrays. First, photoresist is spin-coated onto the substrate, soft baked, and exposed as normal. After developing, an array of photoresist cylinders remains. The resist cylinders are then placed onto a hotplate that is set above its glass transition temperature, causing the polymerous resist to abruptly transition from its amorphous rubbery state into a glass state system. The surface tension minimizes the surface area by rearranging the liquid masses inside of the cylinder/droplet complex. Ideally, the resist melts completely, with masses freely transported and the surface tension forming a spherical microlens. Any deviation from this reflow condition (either via temperature fluctuations, surface morphology, or time) can have an outsized impact on the final lens morphology.

Theoretically, the volume of the lens is related to the initial cylinder parameters, but the final volume is generally lower due to outgassing and polymer crosslinking.

Equation 2.1 below relates the final volume of the lens (V_{L}) to the height of the lens (h_{L}) and the radius of curvature (ROC). The height of the lens, in practice, is generally 1.3-1.7 times higher than the resist cylinder before melting, and that value can only be determined experimentally. [18]

$${v}_{L} = \frac{1}{3} π {h}_{L}^{2} ( 3 ROC - {h}_{L} ) \qquad ( 2.1 )$$

Equation 2.2 below shows how the ROC is impacted by changes in the lens height, where r describes the radius of the optical axis, and K is a value that is either 0 (spherical), −1 (parabolic), or a more sophisticated value and shape.

$$ROC = ( K + 1 ) \frac{{h}_{L}}{2} + \frac{{r}^{2}}{2 {h}_{L}} \qquad ( 2.2 )$$

Experimentally, high quality lenses have been demonstrated using many of the positive photoresists available in the UCSB nanofabrication facilities, and K is generally assumed to be 0.

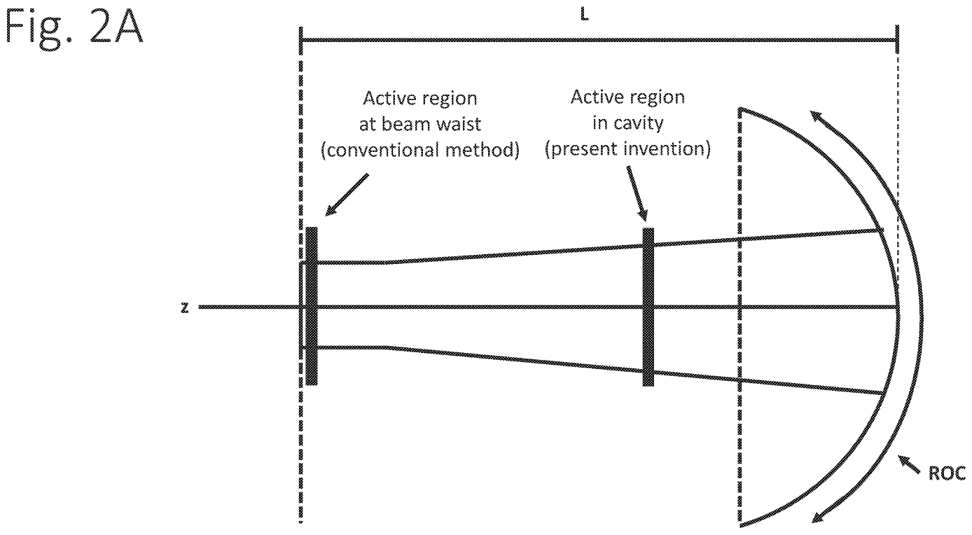

Assuming the lens is perfectly spherical, a given ROC will have an impact on the cavity dynamics, including the initial beam size as well as how quickly it expands throughout the cavity. For the VCSEL design currently being pursued at UCSB, the distance from the planar DBR to the active region is approximately 7 μm. Since it is far away from the planar side (recall that Sony's active region is within 100 nm), the assumption that the overlap between the active region and the beam occurs at the beam waist is no longer valid as the beam expands through the cavity. FIG. 2A shows this key difference between the two designs. Assuming the beams are Gaussian, a resonator with a curved mirror and a planar mirror will create a beam waist (Wo) at the planar mirror that can primarily be described by the length of the cavity (L) and ROC (Equation 2.3 below).

$${w}_{o} = \sqrt{\frac{λ}{n π} \sqrt{L * ROC - {L}^{2}}} \qquad ( 2.3 )$$

As the beam travels through the cavity, it expands, and the beam profile at an arbitrary value w(z) is determined by the initial beam waist as well as the position (z) in the cavity (Equation 2.4 below). Note that the additional prefactor of 4 out front of Equation 2.4 is added to include 99.997% of the light (such that loss due to scattering is kept below 0.1% per pass).

$$w ( z ) = 4 {w}_{o} \sqrt{1 + {( \frac{λ z}{π n {w}_{o}^{2}} )}^{2}} \qquad ( 2.4 )$$

FIG. 2B shows the expected growth of the beam profile diameter (analogous to current aperture) for a 13 μm cavity for different ROC values of 15 μm, 30 μm and 45 μm. For values of ROC close to the cavity thickness, the beam diverges rapidly, opening up the possibility for wide aperture, high power cavity designs.

Creating this dynamic where the active region is placed far away from the beam waist, and in the path of a diverging beam, has implications for possible device designs and applications. Sony's current aperture width is limited by the initial width of the beam waist, which only scales with ROC to the square root of the fourth power (Equation 2.3); for a 10 μm aperture to optimally overlap with a 10 μm beam, Sony's curved lens would need an ROC of 4,000 μm. Assuming the thickness of the lens is 12 μm after the reflow process, and assuming the lens volume does not shrink, the lens would need to be 300 μm wide to attain the requisite ROC. This large of a lens would lower packing density, and in general, is not favored for array-based applications. By contrast, by placing the active region farther away from the beam waist and in the path of the diverging beam, it is possible to use wider apertures. For example, a 13 μm cavity capped with a lens with an ROC of 15 μm creates a beam with a diameter of 9 μm, and the overall lens diameter is less than 20 μm. This design does have drawbacks, including a wider divergence angle. Taking this into consideration, this VCSEL design has the most potential for high power directional lighting applications, or other applications where an array of VCSELs with a wide divergence angle is of interest.

NP-DBR Design Considerations

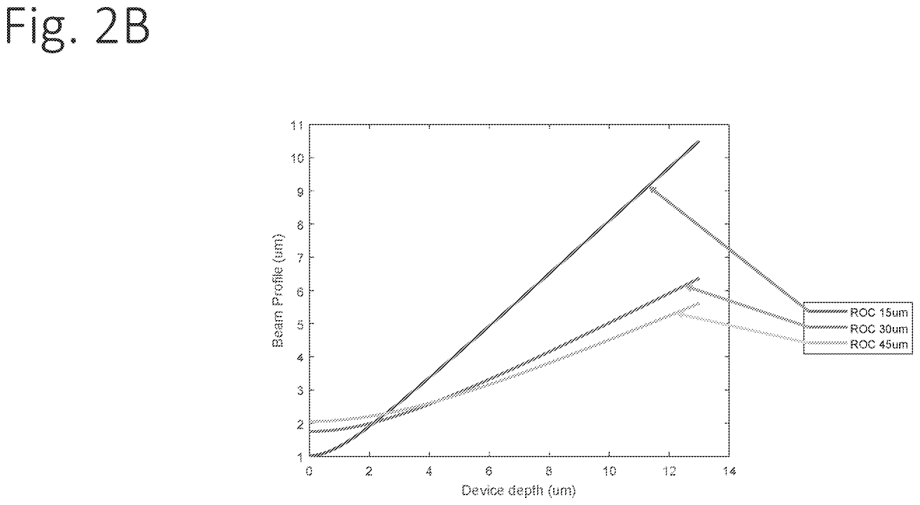

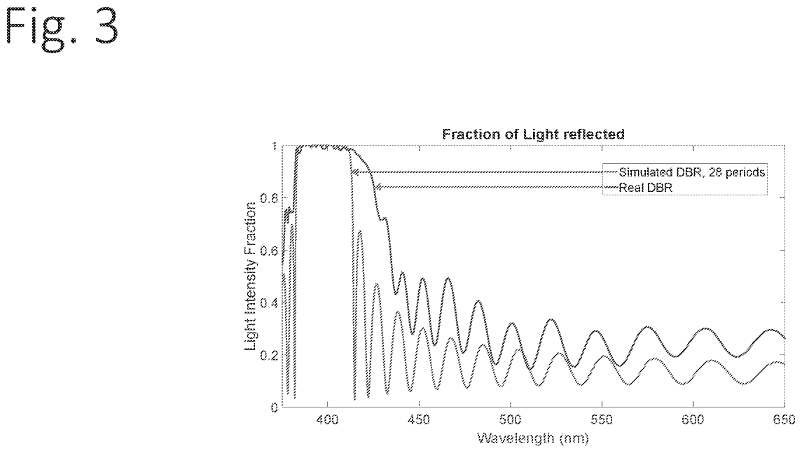

NP-DBRs have shown promise in GaN VCSELs due to their lattice match to GaN, relative ease of growth and fabrication, and high refractive index contrast. The formation of NP-GaN has been studied extensively, and the mechanism of etching is well understood. [21] Electrochemical (EC) etching of GaN in oxalic acid is conductivity selective and spatially isotropic, meaning that at a given applied bias, the size and shape of pores is directly related to the n-type doping and the crystal orientation of the layers exposed to the solution. During the etching reaction, four continuous processes occur: (1) the negative applied bias creates a hole inversion layer at the electrolyte/n-GaN interface, (2) the n-GaN surface is oxidized due to the presence of holes at the inverted surface, (3) oxidized GaN dissolves into Ga³⁺ and nitrogen gas products, which (4) migrate freely into the electrolyte, leaving behind mesoporous or nanoporous voids. The ratio between the size of the pores and the surrounding walls is determined by the depletion width between the surrounding n-GaN and the inverted hole tip. At a given doping and voltage, charge equilibrium is reached between the depleted sidewalls and hole-rich pore center, influencing pores to etch in a unified direction. As the voltage increases, the depletion region between neighboring pores decreases, until the sidewalls collapse and the nanopores become a large void. These voids can increase scattering loss from the NP-DBR [22], and so the etch voltage is chosen to minimize the presence of macro-voids. FIG. 3 shows an optimized NP-DBR compared to a 1D transmission matrix model in a graph of Light Intensity Fraction vs. Wavelength (nm), where the refractive index (nₚₒᵣ) of the porous layer is calculated using the volume average theory (VAT) of Equation 3.1 below:

$${n}_{por} \approx \sqrt{( 1 - φ ) {n}_{GaN}^{2} + φ {n}_{air}^{2}} \qquad ( 3.1 )$$

Here, q is the porosity, n_{GaN}, and nₐᵢᵣ are the refractive index of GaN and air, respectively. The optimized porosity of 36% yields an effective nanoporous refractive index of 2.092 at 405 nm, leading to an index contrast of 0.41 (approximately double the index contrast of a lattice-matched AlInN/GaN layer) and a full-width half-percent max (FWHPM) of 22 nm for a 20-period DBR.

### Initial VCSEL Fabrication and Troubleshooting

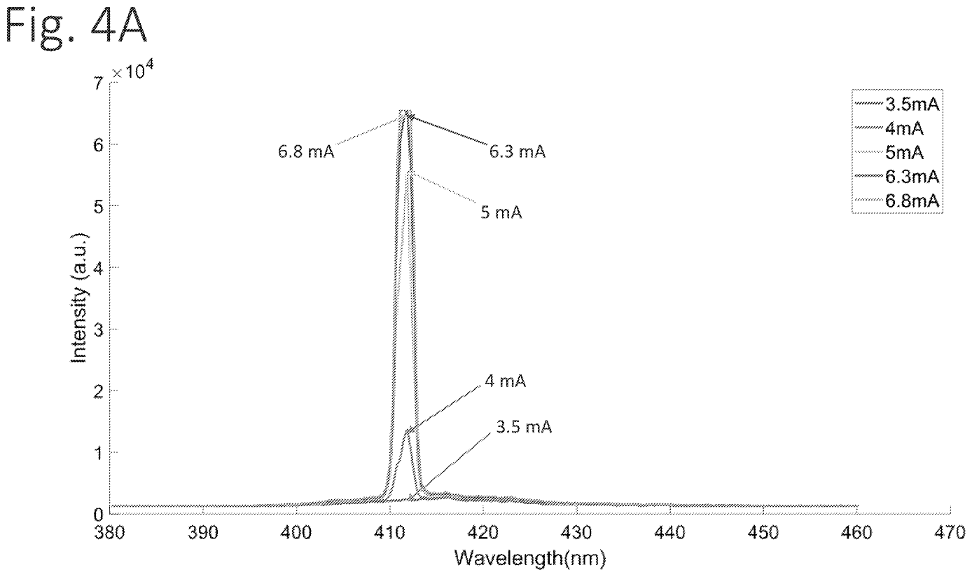

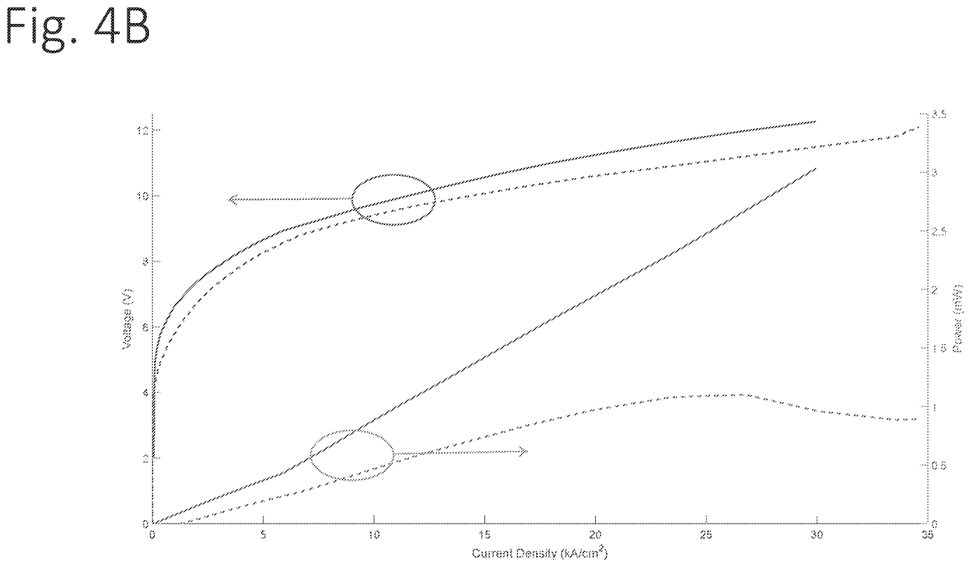

Using the structures outlined above, VCSEL devices were fabricated. FIG. 4A is a graph of Intensity (a.u.) vs. Wavelength (nm) that shows the spectrum of a 9 μm aperture VCSEL under pulsed operation (1000 ns) and 1% duty cycle below and above threshold. The clamping of the spontaneous emission above threshold, combined with the rapid increase in mode intensity as a function of increasing current, is strong evidence for lasing. Polarization measurements (not shown) confirm that the mode is 100% polarized in the a-direction, a characteristic typical of m-plane VCSELs. [24] FIG. 4B is a graph of Voltage (V) and Power (mW) vs. Current Density (kA/cm²) that shows LJV characteristics of the device, with the solid line showing performance under pulsed (1000 ns, 1% duty cycle) condition and the dotted under continuous-wave (CW) condition. Note that due to scattering at the bottom of the substrate, the characteristic kink in the LJ curve expected at the onset of lasing is less visible under CW, but lasing was confirmed via spectrum measurements (not shown). Peak output power under pulsed condition was 3.1 mW, and peak power under CW was 1.07 mW, both record performances for VCSELs at UCSB. Additionally, FIGS. 4C and 4D are nearfield images of a 9 μm VCSEL below and above threshold. The bright spot in the center of the aperture matches the expected calculated width of a Gaussian mode within the same cavity, evidence that the lens encourages a fundamental mode to arise. This fundamental lateral mode, single longitudinal mode emission would be the first demonstration of such behavior from III-nitride-based TJ VCSELs from UCSB, as previous VCSELs have demonstrated higher order modes due to current crowding.

### P-Side Dielectric Lens

While the VCSELs with a monolithic GaN lens successfully lased, the best threshold current, 6 kA/cm², was significantly higher than previously reported VCSELs utilizing a curved mirror. [5] Additionally, the peak output power was significantly lower, pointing to issues with the active region intensity. Since the initial light-current-voltage (LIV) test results on the as-grown epitaxial wafers were suitably high (data not shown), attention was directed towards the thick regrowth condition as a possible culprit. To fabricate lenses with the correct dimensions (ROC 15 μm, 30 μm, height of 3 μm), the III-nitride regrowth on top of the buried tunnel junctions (BTJs) needs to be roughly 3,000 nm; this condition has a slow growth rate, leading to extended time where the active region is subject to high temperatures at or above 900° C. The effect of the regrowth condition on the active region was tested in a series of anneals designed to simulate the regrowth condition but without growing significant amounts of GaN, which would absorb the light and affect subsequent measurements. The anneals were carried out in the reactor at different temperatures and regrowth times; 1000° C. for 90 min; 900° C. for 75 min; and 850° C. for 75 min. Each anneal was carried out in a low NH₃ environment with a 5 sccm TEG flow to prevent etching of the substrate.

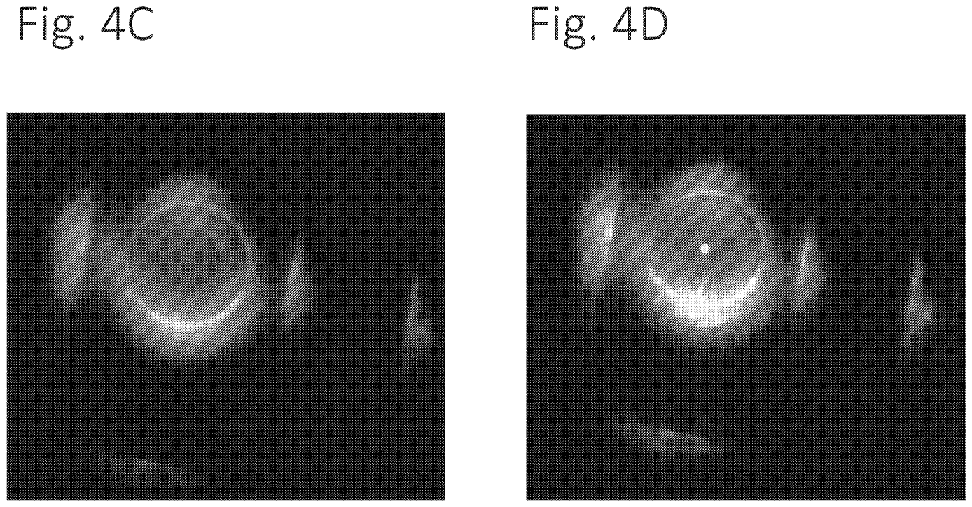

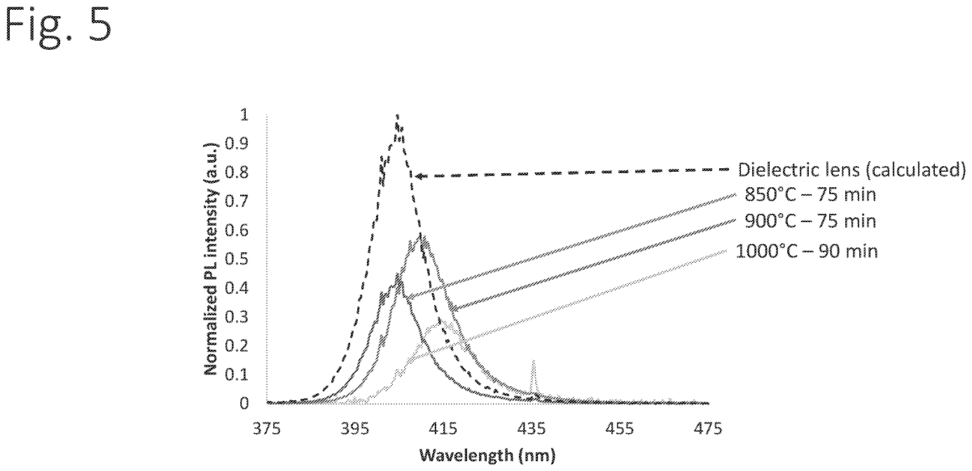

Normalized photoluminescence data (PL) is plotted in FIG. 5, which is a graph of Normalized PL Intensity (a.u.) vs. Wavelength (nm) showing the normalized PL intensities of active regions subjected to various regrowth conditions compared to calculated PL emission intensity using a dielectric lens, with each spectrum normalized relative to its PL spectrum taken just before loading into the reactor. The data shows that all three regrowth conditions damage the active region, with the three growth temperatures, 850° C., 900° C., and 1000° C., reducing the intensity of the active region by 60%, 50%, and 70%, respectively. This decrease in intensity is likely due to non-radiative recombination centers in the active region that are generated by the elevated temperatures, and while only a proxy, is likely a reflection of the reduction in gain experienced by the VCSEL. To combat this reduction in gain, the lens material can be replaced with a dielectric material, which can be deposited at or near room temperature, preventing any degradation of the active region (in other words, the normalized intensity would be approximately 1 after deposition, calculated example shown in FIG. 5). This increase in the active region intensity effectively translates to an equivalent increase in the active region material gain, causing the VCSEL to lase at lower threshold current densities and allow for higher peak output powers. Additionally, UID GaN and lightly doped n-GaN contribute to absorption within the cavity, further impacting threshold currents. A properly optimized dielectric lens materials should be nearly lossless in terms of absorption, which will further reduce the threshold. 1D transmission matrix modeling of a 13 μm VCSEL cavity found that replacing 3,000 nm of n-GaN (absorption coefficient ~1 cm⁻¹) with 3,000 nm of SiO₂ (absorption coefficient ~0 cm⁻¹) reduces the round-trip loss (RTL) by 14%, from 0.53% RTL to 0.45% RTL. Taking this further, depositing the top-side DBR onto a photoresist lens and then removing the photoresist underneath the lens would create an air-gap lens, providing a further reduction in RTL. Making this improvement will make the top-side lens design competitive with conventional bottom-side lens designs.

### Activation of Planar Tunnel Junctions

Due to the high hydrogen environment of MOCVD, the magnesium acceptors in p-GaN are passivated with hydrogen. While these acceptors can be activated through thermal annealing, in which the hydrogen diffuses out of the sidewalls, UCSB implements buried TJs, which are buried below a larger n-GaN layer, as shown in FIGS. 1A, 1B and 1C. [30-32] The n-GaN acts as a barrier, preventing hydrogen from diffusing out of the top surface, leading to a reduced activation efficiency of p-GaN, and resulting in a larger turn-on voltage. [33,34]

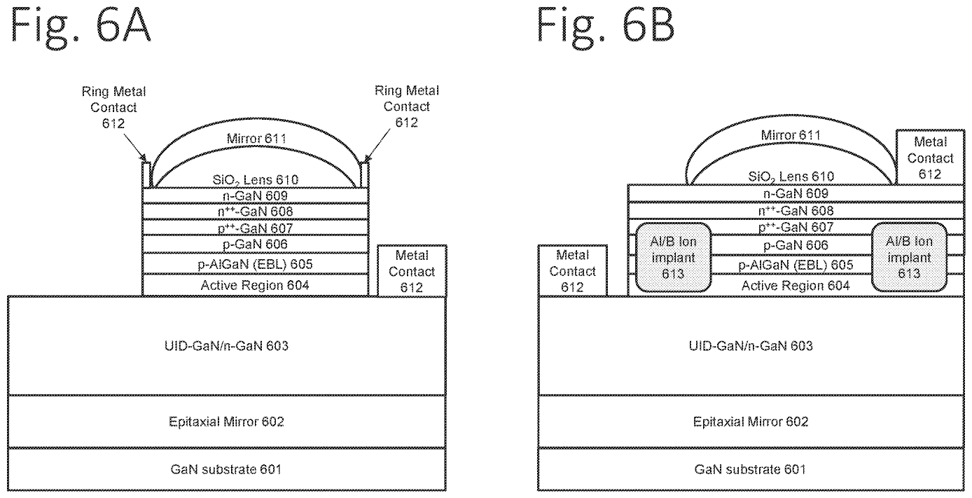

To activate the GaN TJ, a planar tunnel junction is implemented just below the curved mirror, as shown in FIGS. 6A and 6B, which include a GaN substrate 601, epitaxial mirror 602, UID-GaN/n-GaN 603, active region 604, p-AlGaN EBL 605, p-GaN 606, p++-GaN 607, n++-GaN 608, n-GaN current spreader 609, SiO₂ lens 610, mirror 611, metal contacts 612, and Al/B ion implants 613.

In this embodiment, the device mesas are etched close to the edge of the metal contacts 612. The small size of the mesas allows for sidewall activation of p-GaN 606, 607. Chemical treatments can also be implemented to further improve sidewall activation. [39,30]

During etching, the sidewalls of the devices will be damaged by the plasma required for dry etching. This etch damage can result in defects which present a diffusion barrier to hydrogen. By implementing a phosphoric acid dip, ultraviolet-ozone treatment, and buffered hydrofluoric acid dip, the damaged sidewall can be removed, improving the efficiency of sidewall activation. This will reduce the turn-on voltage, resulting in higher wall-plug efficiency.

This creates a TJ with an activated p⁺⁺ GaN layer 607. However, as the p⁺⁺ GaN 607 extends to the edge of the device, no current aperture is formed. The structure of the VCSEL can be designed to improve the overlap of the beam with the active region 604, removing the need for a current confinement layer. The mesa can be etched close to the outside of the lens 610, leaving a small space for a top-side p-contact 612, as shown in FIG. 6A. This physically restricts the current to the area around the lens 610. However, the lens 610 focuses light to a width smaller than the lens itself. To solve this issue, the lens 610 can be deposited directly on top of the TJ 607, 608, with removing any top-side n-GaN 609 cavity. This places the mirror 611 close to the active region 604, within ~500 nm. The beam size decreases with distance from the mirror 611, so by placing the active region 604 close to the mirror 611, most of the width of the active region 604 can be in the path of the beam.

To improve current confinement in a larger aperture design, ion implantation 613 of aluminum (Al) or boron (B) can be utilized to form a current aperture, as shown in FIG. 6B. [27, 40, 41] The ions damage the GaN crystal lattice, which in turn blocks electrons flowing through the regions 613 where ion implantation was used. By implanting ions on the side of the mesas to below the active region 604, a current aperture can be created to direct the flow of current to the middle of the device, where the beam is focused, resulting in a higher density of carriers in the active region 604 and therefore higher gain.

### Process Steps for Fabrication

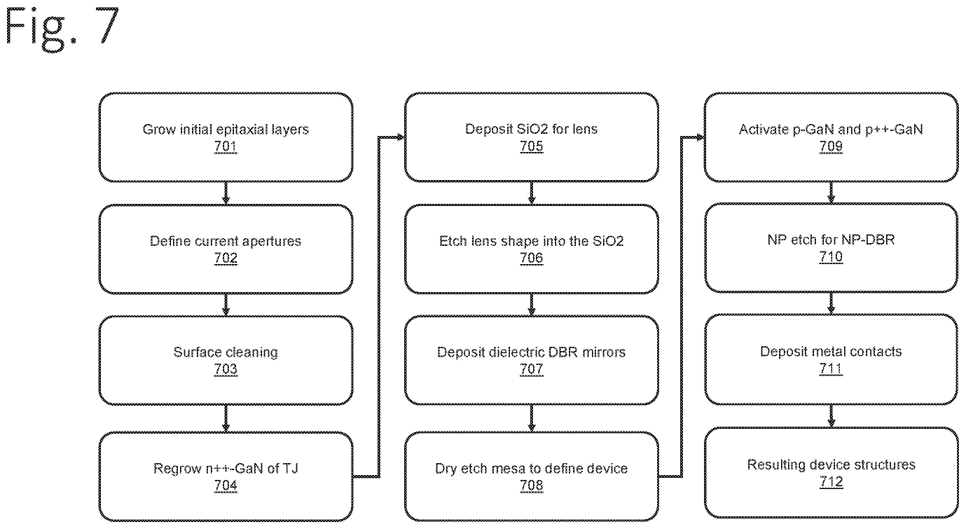

FIG. 7 is a flowchart illustrating an example process for fabricating the epitaxial device structure, includes the following steps:

Block 701 represents the steps of growing the initial epitaxial layers of the samples using atmospheric MOCVD on a GaN substrate, as follows: base epi-layers of an epitaxial DBR, UID-GaN, n-GaN for n-contacting, InGaN active region, AlGaN electron blocking layer (EBL), p-GaN, and p++-GaN.

Block 702 represents the steps of defining the current apertures using ion implantation or reactive ion etching (RIE).

Block 703 represents the steps of surface cleaning.

Block 704 represents the steps of regrowing n++ GaN to complete the TJ and regrowing n-GaN for contacting and current spreading.

Block 705 represents the steps of depositing SiO₂ for forming the lens.

Block 706 represents the steps of using thermal reflow of photoresist and etching a lens shape having curved surfaces in the SiO₂ to the n-GaN with RIE.

Block 707 represents the steps of depositing dielectric DBR mirrors over the curved surfaces.

Block 708 represents the steps of dry etching mesas to define the devices.

Block 709 represents the steps of thermal activating the p-GaN and p++-GaN through sidewalls of the mesas.

Block 710 represents the steps of performing an NP etch (if an NP-DBR is used), including steps to protect the device from the NP etch.

Block 711 represents the steps of depositing metal contacts.

Block 712 represents the results of the process, namely, the resulting device structures.

### Summary

A dielectric p-side lens provides the mode control characteristics of a top-side GaN lens, but eliminates the degradation to the active region that currently occurs with the growth of top-side GaN lens, as well as reduce absorption losses within the cavity. Using the present invention, the output power of the VCSEL is increased dramatically. Threshold current density is reduced, and then external quantum efficiency (EQE) is increased. Thus, present invention could open a lot of applications of the VCSELs for the display, lighting, communications and etc.

Moreover, the use of a planar tunnel junction in a III-nitride-based VCSEL is a viable way to improve device performance by reducing losses within the cavity, as well as reducing turn-on voltage of the tunnel junction through sidewall treatment and activation. A small device mesa or an ion implantation aperture can be used to confine current, resulting in increased gain and efficiency.

### REFERENCES

The following references are incorporated by reference herein.
1. Michalzik, R. VCSELs-Fundamentals, Technology and Applications of Vertical-Cavity Surface-Emitting Lasers. Springer.
2. Lu, T.-C., Kao, C.-C., Kuo, H.-C., Huang, G.-S. & Wang, S.-C. CW lasing of current injection blue GaN-based vertical cavity surface emitting laser. Appl. Phys. Lett. 92, 141102 (2008).
3. Hamaguchi, T. et al. Highly efficient operation and uniform characteristics of curved mirror vertical-cavity surface-emitting lasers. Appl. Phys. Express 16, 012006 (2023).
4. Nakajima, H. et al. Single transverse mode operation of GaN-based vertical-cavity surface-emitting laser with monolithically incorporated curved mirror. Appl. Phys. Express 12, 084003 (2019).
5. Hamaguchi, T. et al. Sub-milliampere-threshold continuous wave operation of GaN-based vertical-cavity surface-emitting laser with lateral optical confinement by curved mirror. Appl. Phys. Express 12, 044004 (2019).
6. Hamaguchi, T., Tanaka, M. & Nakajima, H. A review on the latest progress of visible GaN-based VCSELs with lateral confinement by curved dielectric DBR reflector and boron ion implantation. Jpn. J. Appl. Phys. 58, SC0806 (2019).
7. Kogelnik, H. & Li, T. Laser Beams and Resonators. Appl. Opt. 5, 1550-1567 (1966).
8. Hayashi, K. et al. Narrow emission of blue GaN-based vertical-cavity surface-emitting lasers with a curved mirror. In 2021 27th International Semiconductor Laser Conference (ISLC) 1-2 (2021). Doi: 10.1109/ISLC51662.2021.9615750.
9. Kearns, J. A. et al. Mode control in long cavity VCSELs with a curved mirror. In Gallium Nitride Materials and Devices XVII vol. 12001 52-57 (SPIE, 2022).
10. Zhang, C., ElAfandy, R. & Han, J. Distributed Bragg Reflectors for GaN-Based Vertical-Cavity Surface-Emitting Lasers. Appl. Sci. 9, 1593 (2019).
11. Tao, R., Arita, M., Kako, S. & Arakawa, Y. Fabrication and optical properties of non-polar III-nitride air-gap distributed Bragg reflector microcavities. Appl. Phys. Lett. 103, 201118 (2013).
12. Lee, S.-M. et al. Optically pumped GaN vertical cavity surface emitting laser with high index-contrast nanoporous distributed Bragg reflector. Opt. Express 23, 11023-11030 (2015).
13. Mishkat-Ul-Masabih, S. M., Luk, T. S., Monavarian, M. & Feezell, D. F. Polarization-pinned emission of a continuous-wave optically pumped nonpolar GaN-based VCSEL using nanoporous distributed Bragg reflectors. Opt. Express 27, 9495-9501 (2019).
14. Mishkat-Ul-Masabih, S. M., Aragon, A. A., Monavarian, M., Luk, T. S. & Feezell, D. F. Electrically injected nonpolar GaN-based VCSELs with lattice-matched nanoporous distributed Bragg reflector mirrors. Appl. Phys. Express 12, 036504 (2019).
15. Elafandy, R. T. et al. GaN blue vertical-cavity surface-emitting lasers using conductive nanoporous distributed Bragg reflectors. In Light-Emitting Devices, Materials, and Applications XXV vol. 11706 135-142 (SPIE, 2021).
16. Elafandy, R. T. et al. Study and Application of Birefringent Nanoporous GaN in the Polarization Control of Blue Vertical-Cavity Surface-Emitting Lasers. ACS Photonics 8, 1041-1047 (2021).
17. Monavarian, M., Rashidi, A. & Feezell, D. A Decade of Nonpolar and Semipolar III-Nitrides: A Review of Successes and Challenges. Phys. Status Solidi A 216, 1800628 (2019).
18. Nussbaum, P., Volkel, R., Herzig, H. P., Eisner, M. & Haselbeck, S. Design, fabrication and testing of microlens arrays for sensors and microsystems. Pure Appl. Opt. J. Eur. Opt. Soc. Part A 6, 617-636 (1997).
19. Jucius, D. et al. Effect of fused silica surface wettability on thermal reflow of polymer microlens arrays. Microsyst. Technol. 23, 2193-2206 (2017).
20. Tan, S. L. et al. High pulsed power VCSEL arrays with polymer microlenses formed by photoacid diffusion. Opt. Express 28, 20095 (2020).
21. Zhang, C. et al. Toward Quantitative Electrochemical Nanomachining of III-Nitrides. J. Electrochem. Soc. 165, E513-E520 (2018).
22. Anderson, R. et al. Nano-porous GaN cladding and scattering loss in edge emitting laser diodes. Opt. Express 30, 2759-2767 (2022).
23. Zhang, C. et al. Mesoporous GaN for Photonic Engineering-Highly Reflective GaN Mirrors as an Example. ACS Photonics 2, 980-986 (2015).
24. Forman, C. A. et al. Continuous-wave operation of m-plane GaN-based vertical-cavity surface-emitting lasers with a tunnel junction intracavity contact. Appl. Phys. Lett. 112, 111106 (2018).
25. Wong, M. S. et al. Effects of activation method and temperature to III-nitride micro-light-emitting diodes with tunnel junction contacts grown by metalorganic chemical vapor deposition. Appl. Phys. Lett. 119, 202102 (2021).
26. Wong, M. S. et al. High efficiency of III-nitride micro-light-emitting diodes by sidewall passivation using atomic layer deposition. Opt. Express 26, 21324-21331 (2018).
27. Leonard, J. T. et al. Nonpolar III-nitride vertical-cavity surface-emitting lasers incorporating an ion implanted aperture. Appl. Phys. Lett. 107, 011102 (2015).
28. Leonard, J. T. et al. Demonstration of a III-nitride vertical-cavity surface-emitting laser with a III-nitride tunnel junction intracavity contact. Appl. Phys. Lett. 107, 091105 (2015).
29. Malinverni, M., Martin, D. & Grandjean, N. InGaN based micro light emitting diodes featuring a buried GaN tunnel junction. Appl. Phys. Lett. 107, 051107 (2015).
30. Lee, S. et al. Demonstration of GaN-based vertical-cavity surface-emitting lasers with buried tunnel junction contacts. Opt. Express 27, 31621 (2019).
31. Kearns, J. A. et al. Inhomogeneous Current Injection and Filamentary Lasing of Semipolar (2021) Blue GaN-Based Vertical-Cavity Surface-Emitting Lasers with Buried Tunnel Junctions. Phys. Status Solidi A 217, 1900718 (2020).
32. Nakamura, S., Mukai, T., Senoh, M. & Iwasa, N. Thermal Annealing Effects on P-Type Mg-Doped GaN Films. Jpn. J. Appl. Phys. 31, L139-L142 (1992).
33. Neugebauer, J. & Van de Walle, C. G. Hydrogen in GaN: Novel Aspects of a Common Impurity. Phys. Rev. Lett. 75, 4452-4455 (1995).
34. Limpijumnong, S. & Van de Walle, C. G. Stability, diffusivity, and vibrational properties of monatomic and molecular hydrogen in wurtzite GaN. Phys. Rev. B 68, 235203 (2003).
35. Li, P. et al. Size-independent low voltage of InGaN micro-light-emitting diodes with epitaxial tunnel junctions using selective area growth by metalorganic chemical vapor deposition. Opt. Express 28, 18707 (2020).
36. Nussbaum, P., Volkel, R., Herzig, H. P., Eisner, M. & Haselbeck, S. Design, fabrication and testing of microlens arrays for sensors and microsystems. Pure Appl. Opt. J. Eur. Opt. Soc. Part A 6, 617-636 (1997).
37. Jucius, D. et al. Effect of fused silica surface wettability on thermal reflow of polymer microlens arrays. Microsyst. Technol. 23, 2193-2206 (2017).
38. Tan, S. L. et al. High pulsed power VCSEL arrays with polymer microlenses formed by photoacid diffusion. Opt. Express 28, 20095 (2020).
39. Wong, M. S. et al. Demonstration of high wall-plug efficiency III-nitride micro-light-emitting diodes with MOCVD-grown tunnel junction contacts using chemical treatments. Appl. Phys. Express 14, 086502 (2021).
40. Hamaguchi, T., Nakajima, H. & Fuutagawa, N. GaN-based Vertical-Cavity Surface-Emitting Lasers Incorporating Dielectric Distributed Bragg Reflectors. Appl. Sci. 9, 733 (2019).
41. Hamaguchi, T. et al. Lateral optical confinement of GaN-based VCSEL using an atomically smooth monolithic curved mirror. Sci. Rep. 8, 10350 (2018).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A device, comprising:
a vertical cavity surface emitting laser (VCSEL), comprising:
a III-nitride active region formed between a p-type III-nitride layer and an n-type III-nitride layer; and
a curved mirror formed on or above the p-type III-nitride layer, wherein the p-type III-nitride layer is between the III-nitride active region and the curved mirror.

2. The device of claim 1, wherein the VCSEL further comprises at least one tunnel junction formed on the p-type III-nitride layer, and the curved mirror is formed on or above the tunnel junction, such that the tunnel junction is positioned between the curved mirror and the p-type III-nitride layer.

3. The device of claim 2, wherein the tunnel junction is a planar tunnel junction, and a p++-type III-nitride layer of the planar tunnel junction is activated through a sidewall of the VCSEL.

4. The device of claim 3, wherein the p++-type III-nitride layer extends to the sidewall of the VCSEL.

5. The device of claim 4, wherein an ion-implantation current aperture confines current in the III-nitride active region, resulting in increased gain and efficiency.

6. The device of claim 5, wherein the ion-implantation current aperture allows for activation of the p-type III-nitride layer and a p++-type III-nitride layer.

7. The device of claim 5, wherein the ion-implantation current aperture is fabricated by ion implantation of aluminum (Al) or boron (B).

8. The device of claim 2, wherein the VCSEL further comprises a second n-type III-nitride region formed on or above the tunnel junction, the curved mirror includes the second n-type III-nitride region, and the second n-type III-nitride region has a curvature forming the curved mirror.

9. The device of claim 8, wherein the second n-type III-nitride region has an etched surface having the curvature.

10. The device of claim 1, wherein the curved mirror comprises a dielectric material that is transparent, the dielectric material's surface has a curvature, and a distributed Bragg reflector (DBR) is deposited upon the dielectric material's surface.

11. The device of claim 10, wherein the dielectric material is removed by dry or wet etching after disposition of the DBR, resulting in a curved DBR mirror separated from other layers by an empty or gas-filled void.

12. The device of claim 1, wherein the VCSEL further comprises one or more transparent oxide (TO) layers on the p-type III-nitride layer, and the curved mirror is formed on or above the TO layers, such that the TO layers are between the curved mirror and the p-type III-nitride layer.

13. The device of claim 1, wherein the VCSEL further comprises a flat distributed Bragg reflector (DBR) mirror, the curved mirror comprises a curved DBR mirror, the III-nitride active region is between the flat DBR mirror and the curved DBR mirror, and the flat DBR mirror and the curved DBR mirror define a cavity of the VCSEL.

14. The device of claim 1, wherein a mesa of the VCSEL is etched to an outside of the curved mirror, to restrict the current to an area around the curved mirror.

15. The device of claim 1, wherein the curved mirror is close enough to the III-nitride active region that most of the width of the III-nitride active region is in the path of the light beam.

16. The device of claim 1, further comprising an n-type III-nitride current spreading layer between the tunnel junction and the curved mirror.

17. A method, comprising:
fabricating a vertical cavity surface emitting laser (VCSEL), comprising:
a III-nitride active region formed between a p-type III-nitride layer and an n-type III-nitride layer; and
a curved mirror formed on or above the p-type III-nitride layer, wherein the p-type III-nitride layer is between the III-nitride active region and the curved mirror.

18. The method of claim 17, wherein the VCSEL further comprises at least one tunnel junction formed on the p-type III-nitride layer, and the curved mirror is formed on or above the tunnel junction, such that the tunnel junction is positioned between the curved mirror and the p-type III-nitride layer.

19. The method of claim 18, wherein the tunnel junction is a planar tunnel junction, and a p++-type III-nitride layer of the planar tunnel junction is activated through a sidewall of the VCSEL.

20. The method of claim 19, wherein the p++-type III-nitride layer extends to the sidewall of the VCSEL.
